(19) United States
(12) Patent Application Publication
(10) Pub. No.: US 2007/0241765 A1
(43) Pub. Date: Oct. 18, 2007

(54) Probe card and measuring method for semiconductor wafers

(75) Inventor: Yosuke Kawamata, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/785,112

(22) Filed: Apr. 16, 2007

(30) Foreign Application Priority Data
Apr. 14, 2006 (JP) 2006-111741

(51) Int. Cl. G01R 31/02

(52) U.S. Cl. 324/754

(57) ABSTRACT

A probe card for use in testing wafers for semiconductor devices is provided. In the probe card, a region having a plurality of probes corresponding to respective chips is divided into a plurality of subregions. A tester signal is switched between a pair of subregions thus divided so that the tester signal is supplied to one of the pair of subregions. The object to be measured by the probe card is switched according to chip arrangement on the semiconductor wafer by the switching of the tester signal, whereby useless parts in the periphery of the wafer are eliminated and the measurement efficiency is improved.

This application claims priority to prior Japanese patent application JP 2006-111741, the disclosure of which is incorporated herein by reference.

### BACKGROUND OF THE INVENTION

1. Field of the Invention

The present invention relates to a probe card for measuring semiconductor wafers and, in particular, to a probe card for efficient measurement of semiconductor wafers and a measuring method for semiconductor wafers using such a probe card.

2. Description of the Related Art

In the field of semiconductor devices, the capacity has been increased and the functions have been enhanced year by year. For example, DRAMs (Dynamic Random Access Memories) with a capacity as large as 1 G bits have been commercialized. These semiconductor devices are inspected by manufacturers in several stages of the manufacturing process to make sure that only those determined as non-defective are passed to the next process or shipped. Such inspection includes wafer inspection, product shipping inspection, and so on. The time required for testing semiconductor devices has been increased along with the increase in the capacity of the semiconductor devices. In order to shorten the testing time, some of the manufacturers adopt a parallel measurement method to test a large number of chips at the same time.

As for the inspection of wafers as well, the parallel measurement has increased the number of chips to be tested in parallel to 16, 32 and 64. Actually, the parallel measurement of 256 chips is conducted for current main products, or 12-inch wafers. When chips are tested in the state of a wafer, the design of a probe card is determined to measure the chips arranged in J rows and K columns in parallel. The determination is performed based on an index method such that the whole wafer is covered by a minimum number of repetitions of measurements with the probe card. The term “index method” as used herein collectively refers to a measuring method, including parameters such as a wafer setting position relative to the probe card, a vertical feeding position, and a number of repetitions. In the following description, the act of changing the probe card position is referred to as “index shifting”. The state in which the probe card is set at a measuring position on the wafer is referred as “an index”. The number of moving and touching down the probe card at measuring positions until the whole wafer is covered is referred to as the “number of repetitions”. When the whole wafer is covered by six repetitions, it is referred as six indexes.

FIG. 9 is a diagram for explaining a concept when a wafer is measured by using a conventional probe card for 22 indexes, and FIG. 10 is a diagram for explaining a concept when a wafer is measured by using a conventional probe card for six indexes. As is obvious from these diagrams, a semiconductor wafer 10 is circular and the probe card 11 is quadrangular. Therefore, although a multiplicity of sets of probes are arranged over the whole surface of the quadrangular probe card, there are regions having no chips to measure in the periphery of the probe card, particularly in the four corners thereof (the parts indicated by dots in the figures). This means that, when a quadrangular probe card is used to measure a circular wafer, the four corners of the probe card always become useless. This increases the number of simultaneous measurements (number of indexes). Moreover, the size of the useless regions becomes greater as the size of the probe card is increased, leading to a problem of poor measurement efficiency.

When it is assumed that the number of chips that can be measured simultaneously, that is, the number of chips to be tested in parallel is 256, a 950-chip wafer as shown in FIG. 10 can be theoretically measured by a number of repetitions, 950/256≈3.7, or by four repetitions. In practice, however, six measurements are required, while four repetitions would suffice if there were no useless regions in the periphery (the regions indicated by dots in FIG. 10). Thus, the tester resource is not utilized effectively, and it takes longer time to complete measurement of the whole wafer. This constitutes one of the factors increasing the production costs.

Prior literature relating to the measurement of semiconductor wafers includes the following patent documents. Japanese Laid-Open Patent Publication No. 2003-156527 (Patent Document 1) describes a technique in which pin assignment of a semiconductor testing apparatus is performed based on initialize data to allocate the pins. Japanese Laid-Open Patent Publication No. 2003-7730 (Patent Document 2) discloses a technique in which a pattern recognition position is changed in accordance with a position on a wafer, so that any cracks in a chip are efficiently recognized. Japanese Laid-Open Patent Publication No. H05-326654 (Patent Document 3) describes a technique in which chips dedicated for probing having a chip select circuit are provided, and chips to be measured are sequentially selected and measured by using the chip select circuit. According to Japanese Laid-Open Patent Publication No. H04-262549 (Patent Document 4), the measurement efficiency is improved by the index shifting, with focusing attention to perfectly formed chips. According to Japanese Laid-Open Patent Publication No. H04-236440 (Patent Document 5), all the chips on a wafer are simultaneously measured by a chip testing portion having bump pads.

It is believed that these prior literature references have achieved their respective objects. However, none of them is able to basically solve the problem of poor measurement efficiency associated with the peripheral useless regions as pointed out in this specification. According to Patent Document 4, the measurement efficiency in the peripheral region is improved when the measurement starting position is shifted to the next row. However, the measurement efficiency in the peripheral region is rather poor in the measurement prior to the shifting. Therefore, this is not a basic solution, but corresponds to the prior art examples shown in FIGS. 9 and 10 of this specification. Thus, there still remains the problem unsolved that the measurement efficiency is poor in the peripheral region of a semiconductor wafer when the number of chips to be measured simultaneously is increased.

### SUMMARY OF THE INVENTION

In view of the problems described above, it is an object of the present invention to provide a probe card which is able to improve the efficiency of measurement of a semiconductor wafer, and a measuring method using such a probe card.

The present invention provides a probe card for use in measurement of a semiconductor wafer having a multiplicity of chips arranged thereon. The probe card includes a first region in which a multiplicity of probes for testing the chips are arranged and the first region includes a plurality of pairs of subregions. One of the subregions of at least one of the subregion pairs is selected to be supplied with a tester signal.

Desirably, the subregions of each subregion pair are provided with a substantially same number of sets of probes.

Desirably, the first region includes, at a substantially central part thereof, a second region supplied with a tester signal at every index, and the subregions of each subregion pair are located outside the second region and not adjacent to each other.

Desirably, the plurality of pairs of subregions is four pairs, and one of the subregions in each subregion pair is selected.

It is desirable that one of the subregions in each subregion pair includes a shape conformed to the outline of the chips arranged on the periphery of the wafer.

Desirably, the first region has a polygonal shape, and has convex regions on the periphery thereof.

The upper and lower halves of the first region are symmetrical in shape to each other, and more desirably the right and left halves of the first region are symmetrical in shape to each other.

The probe card includes a switching circuit for switching the tester signal to one of the subregions of each subregion pair.

The present invention provides a method of measuring a semiconductor wafer having a multiplicity of chips arranged thereon. According to the method, a probe card including a first region in which a multiplicity of probes for testing the chips are arranged and which includes a plurality of pairs of subregions is arranged at a predetermined position according to chip arrangement on the semiconductor wafer, and one of the subregions of at least one of the subregion pairs is selected to be supplied with a tester signal.

In the probe card according to the present invention, a region having a plurality of probes corresponding to respective chips is divided into a plurality of subregions. Supply of a tester signal is switched between one and the other subregions of a specific subregion pair of the plurality of pairs of subregions thus divided. Selection of the specific subregion pair and selection between one and the other regions in the pair are determined in accordance with an index position of the probe card to the wafer. In this manner, probes of the probe card in the region where chips are present are activated in accordance with the position of the probe card on the wafer, while probes in the region having no chips are inactivated. This enables effective use of tester signals and thus efficient measurement of the wafer. A 950-chip wafer can be measured by four indexes, while six indexes are required according to the conventional techniques. Consequently, the measurement efficiency is improved by 33%. Further, the efficient measurement can reduce the number of testers required.

### BRIEF DESCRIPTION OF THE DRAWINGS

FIG. 1 shows a concept of a probe card according to the present invention, which is designed to measure a wafer by four indexes;

FIG. 2 shows a circuit for supplying a tester signal to one of a pair of regions in the probe card shown in FIG. 1;

FIG. 3 shows arrangement of the probe card of FIG. 1 and a wafer when measuring one-quarter region of the wafer using the probe card;

FIG. 4 is a diagram showing an arrangement relationship between a probe card and a wafer, and selected regions of the probe card when measuring the entirety of a circular wafer by using the probe card of FIG. 1;

FIG. 5 shows a probe card according to a first embodiment of the present invention which is designed to measure a 950-chip wafer by four indexes with the use of a tester capable of simultaneous measurement of 256 chips at maximum;

FIG. 6 is a diagram for explaining a case in which a 950-chip wafer is measured by four indexes with the use of the probe card shown in FIG. 5;

FIG. 7 shows a probe card according to a second embodiment of the present invention, which is designed to measure a 600-chip wafer by four indexes with the use of a tester capable of simultaneous measurement of 256 chips at maximum;

FIG. 8 is a diagram for explaining a case in which a 600-chip wafer is measured by three indexes with the use of the probe card shown in FIG. 7;

FIG. 9 is a diagram for explaining a case in which a wafer is measured with the use of a conventional probe card designed for 22 indexes; and

FIG. 10 is a diagram for explaining a case in which a wafer is measured with the use of a conventional probe card designed for six indexes.

### DESCRIPTION OF THE PREFERRED EMBODIMENTS

A description will be made of a probe card according to the present invention and a measuring method using the probe card, with reference to the accompanying drawings.

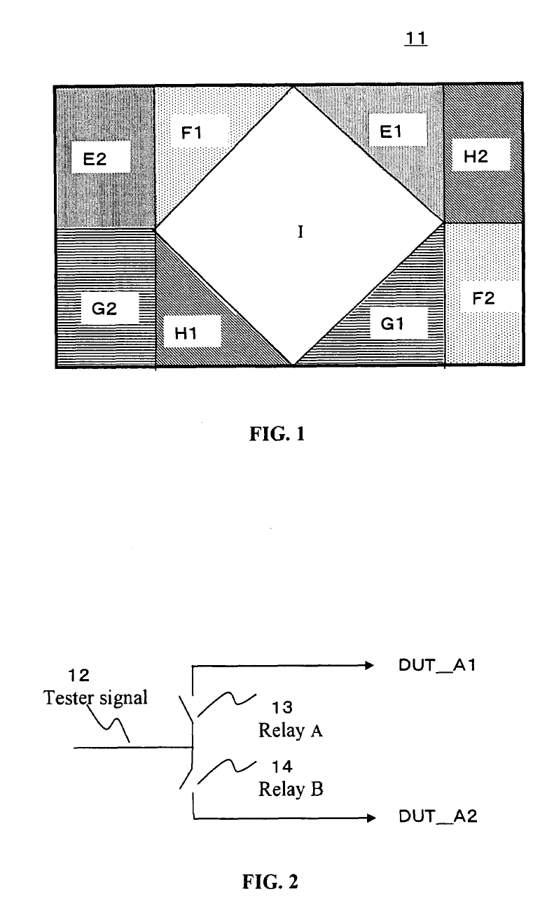

FIG. 1 is a conceptual diagram showing a probe card used for measuring a wafer by four indexes. As seen from FIG. 1, a rectangular probe card 11 has a multiplicity of sets of probes (not shown) arranged perpendicularly to the plane. Each set of probes includes a multiplicity of probes such as power wires and tester signal lines for measuring one chip on the wafer. Conceptionally, the probe card is composed of nine regions, each of which includes sets of probes arranged in a uniform manner. According to the present invention, electric connection between a tester and probes in a certain region of the probe card is switched in accordance with an index position with respect to the wafer, so that a tester signal is effectively used to measure the entirety of the wafer by a smaller number of indexes. The probe card includes a region I, regions E1 and E2, regions F1 and F2, regions G1 and G2, and regions H1 and H2. The region I is located in a central part of the probe card, and is electrically connected to the tester when the probe card is touched down to a predetermined position of the wafer to measure the same. As for the pairs of regions E1 and E2, F1 and F2, G1 and G2, and H1 and H2, electric connection of one and the other regions of each pair to the tester is switched over according to the position where the probe card is touched down to the wafer. Assuming a central line parallel to the upper and lower edges of the probe card and another central line perpendicular to this central line, each pair of regions are arranged on the opposite sides of one of these central lines. Additionally, each pair of regions are located outside the region I and not adjacent to each other.

The electric connection to these pairs of regions is performed for example by a circuit shown in FIG. 2. As shown in FIG. 2, a tester signal supplied by the tester is supplied to a pair of regions via a relay 13 and a relay 14, and is connected to a device to be tested. Although only one tester signal line is indicated as a representative, there are actually a plurality of tester signals corresponding to the probes included in the relevant region.

Selection of a pair from among the plurality of pairs of regions is determined depending on which chips on the wafer are to be measured.

Referring to FIG. 3, a description will be made of a case in which the probe card and the regions of the probe card are applied to measurement of a quarter segment, or a sector portion having a central angle of 90 degrees of a semiconductor wafer.

As shown in FIG. 3, the reference numeral 11 denotes a probe card, and 10 denotes a quarter segment of the semiconductor wafer. The probe card 11 has probes corresponding to respective chips in the entire region of a rectangle LMKJ. A sector aoD indicated by the bold lines in the figure indicates a quarter sector of the circular semiconductor wafer 10. A rectangle having two adjacent sides defined by the two radii forming the central angle of 90 degrees of the quarter sector is defined as a rectangle ABCD. Substantially middle points of the sides AB and AD are defined as E and P, respectively. A rectangle QRCK is determined such that a number of sets of probes in the region (A1) defined by a triangle AEP is substantially equal to a number of sets of probes in the region (A2) defined by the rectangle QRCK. The line ao bisects the region (A2) defined by the rectangle QRCK. The electrical connection such as a tester signal to the probe sets present in the region (A1) defined by the triangle AEP is switched over to the probe sets present in the region (A2) defined by the rectangle QRCK.

In other words, when measuring the upper-left quarter of the wafer, the electrical connection is switched to measure effective chips present in the region defined by a polygon EPDKQRB. Although the probe card 11 has sets of probes for measuring the respective chips in the entire region defined by the rectangle LMKJ, a tester signal for the region (A1) in the periphery of the semiconductor wafer having no chips is switched over, during testing, to the effective chips in the region (A2) in the inside of the wafer to perform more efficient measurement. This pair of regions A1 and A2 respectively correspond to F1 and F2 of the probe card 11 shown in FIG. 1.

Again referring to FIG. 2, the tester signal 12 is branched and controlled so as to be output to either one of the branched destinations. When connected to the relay 13, the tester signal 12 is connected to respective DUT_A1 contained in the region A1, while when connected to the relay 14, the tester signal 12 is connected to respective DUT_A2 contained in the region A2. The switching of the tester signal 12 is performed whenever required. According to this embodiment of the present invention, the switching is performed at each index of the probe card. These relays may be mounted on the probe card, or may be mounted on a test head holding the probe card. Further, the switching may be performed within a semiconductor testing apparatus.

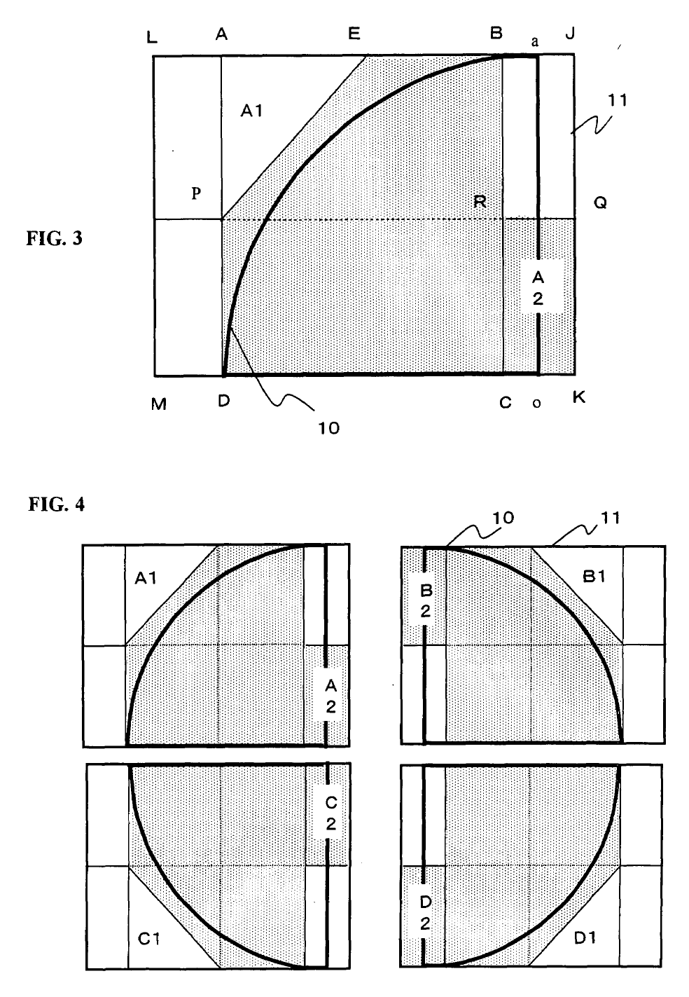

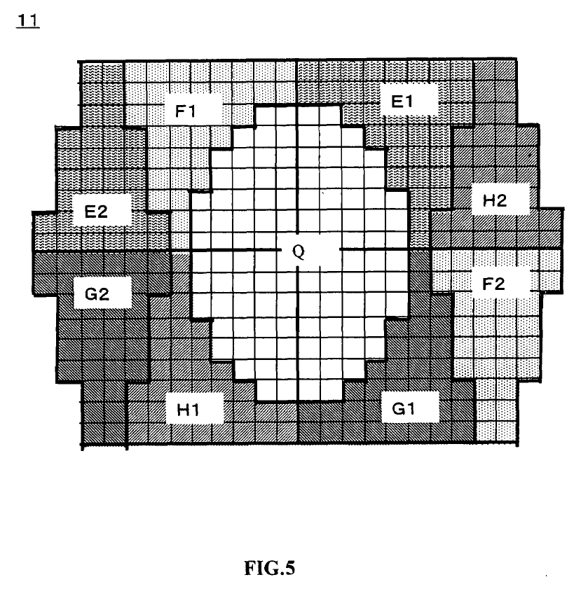

Referring to FIG. 4, a description will be made of a case in which the entirety of the circular semiconductor wafer 10 is measured by using the probe card illustrated in FIG. 1.

Four diagrams of FIG. 4 respectively represent positional relationships between the wafer and the probe card in respective indexes when measuring the entirety of the wafer by four indexes.

When the upper-left quarter of the wafer is to be measured, the tester signal is switched over from the region (A1) to the region (A2). Similarly, when the upper-right quarter of the wafer is to be measured, the tester signal is switched over from the region (B1) to the region (B2). When measuring the lower-left quarter of the wafer, the tester signal is switched over from the region (C1) to the region (C2). When measuring the lower-right quarter of the wafer, the tester signal is switched over from the region (D1) to the region (D2). These pairs of regions A1 and 2, B1 and B2, C1 and C2, and D1 and D2 respectively correspond to F1 and F2, E1 and E2, H1 and H2, and G1 and G2 of the probe card shown in FIG. 1. Accordingly, the measurement is sequentially performed on the chips corresponding to four polygonal regions indicated by the dotted lines. The switching of the tester signal from the peripheral regions to the central regions of the semiconductor wafer enables efficient measurement, eliminating useless supply of signals to the peripheral regions. When measuring the chips corresponding to the four polygonal regions indicated by the dotted lines in FIG. 4, the regions of the probe card shown in FIG. 1 which are supplied with the tester signal are (I, E1, F2, G1, H1), (I, E2, F1, G1, H1), (I, E1, F1, G1, H2), and (I, E1, F1, G2, H1). This means that the region I is supplied with the tester signal in every index.

Preferred embodiments of the present invention will be described with reference to the drawings.

A first embodiment relates to a probe card designed to complete measurement of a 950-chip wafer by four indexes with the use of a tester capable of parallel measurement of 256 chips and having 256 tester signals. This technique is based on an idea that devices under test (hereafter, abbreviated to DUT) are prepared for the probe card in a greater number than 256 so that tester signals to the peripheral regions of the probe card under which chips are not present are transferred to the regions of the probe card under which chips are present, thus utilizing all the tester signals effectively.

FIG. 5 shows a probe card according to a first embodiment of the present invention designed to measure a 950-chip wafer by four indexes with the use of a tester capable of simultaneous measurement of 256 chips at maximum.

As shown in FIG. 5, a probe card 11 is not a quadrangle but a polygon having a plurality of projections on the left and right ends and having upper and lower edges parallel to each other. The upper and lower parts of the probe card 11 are symmetrical to each other, and the left and right parts are also symmetrical to each other. This probe card includes a region Q located at a central part and constantly supplied with a tester signal and pairs of regions which are switchable and located on the periphery thereof. Each pair of the regions having a same pattern (E1 and E2, F1 and F2, G1 and G2, or H1 and H2) are switchable to each other. The regions forming each pair are located on the outside of the region Q and are not adjacent to each other. In each pair of the regions, the region indicated by a reference character with suffix “1” has substantially equivalent to (greater than or equal to) the region indicated by the same reference character with suffix “2”. Probes corresponding to 392 DUTs (chips) are provided in the entirety of the probe card, and each grid cell in the figure corresponds to one DUT (chip).

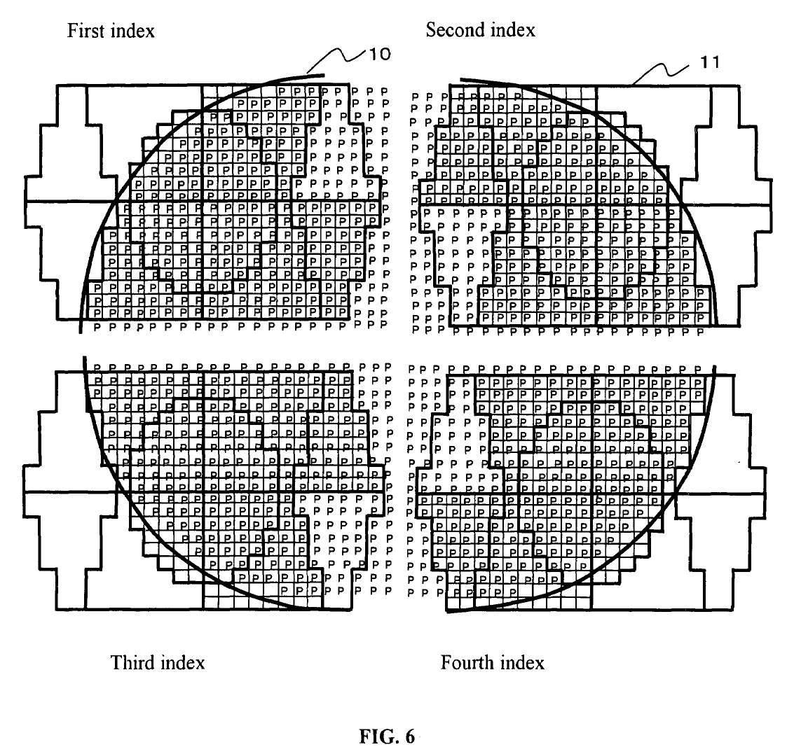

FIG. 6 is a diagram for explaining a case in which a 950-chip wafer is measured by four indexes with the use of the probe card shown in FIG. 5.

As shown in FIG. 6, the probe card is arranged at each index so as to be in best conformity with each quarter region of the wafer, and DUTs (chips) in that region are selected. The entire wafer can be measured by repeating four indexes, the first to fourth indexes. Each grid cell has a set of probes corresponding to each chip, and the reference character P denotes one semiconductor chip. The respective chips P in the grid cells are thus measured. Those regions having no reference character P for the chips are the regions which are supplied with a tester signal but have no chips. In contrast, those regions having no grid cells but having the reference characters P for the chips are not supplied with the tester signal and hence are not measured in the current index. The chips P in these regions are tested in other indexes. The number of chips tested in parallel in each index is 256 DUTs or less.

In the first index, the probe card 11 having 392 sets of probes prepared as shown in FIG. 5 is used, and the tester supplies the probes with a signal capable of measuring 256 chips in parallel. The regions supplied with the signal include the central region Q and the regions E1, G1, H1, and F2. In the second index, the regions Q, F1, G1, H1, and E2 are supplied with the tester signal. In the third index, the regions Q, E1, F1, G1, and H2 are supplied with the tester signal. In the fourth index the regions Q, E1, F1, H1, and G2 are supplied with the tester signal. Since the tester supplies 256 tester signals in each index, the two regions on the left or right end of the probe card 11 are not supplied with the tester signal. In stead of supplying the tester signal to regions adjacent to these regions and outside of the wafer, the tester signal is supplied to the regions in the central part of the wafer.

According to the conventional technique as shown in FIG. 10, a 950-chip semiconductor wafer is measured by six indexes when using a tester capable of simultaneous measurement of 256 chips. According to the first embodiment of the present invention, however, a similar semiconductor wafer can be measured by four indexes.

The probe card of this embodiment is provided with sets of probes corresponding to a greater number of chips than the number of chips that can be measured in parallel by the tester. Further, the probe card is divided into several regions so that the tester signal is supplied to only one of the regions paired by the switching relays. The switching of the tester signal makes it possible that the tester signals addressed to a region in the periphery of the semiconductor wafer where there is no chip can be utilized on the opposite side thereof, and thus the measurement can be performed efficiently. The efficient measurement enables reduction of the number of testers required.

A second embodiment of the present invention will be described.

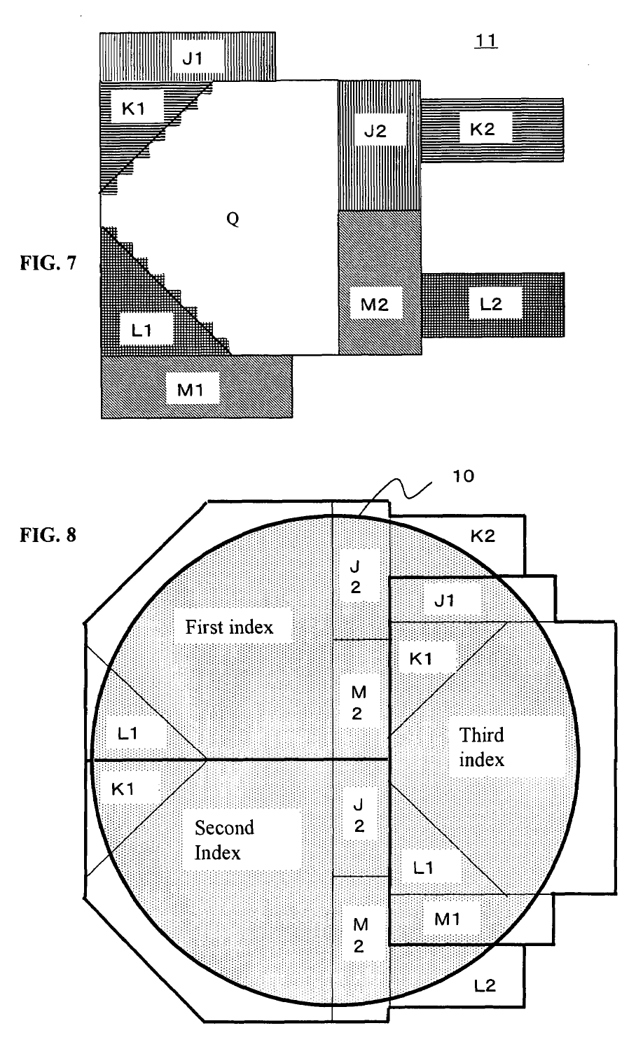

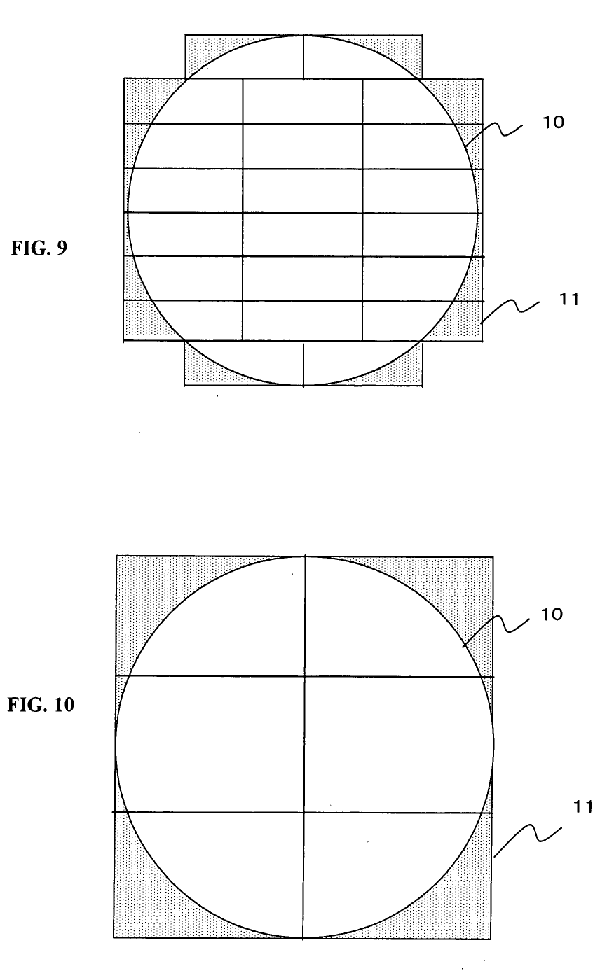

FIG. 7 shows a probe card according to the second embodiment, which is designed to measure a 600-chip wafer by three indexes with the use of a tester capable of simultaneous measurement of 256 chips.

As shown in FIG. 7, a probe card 11 is provided with a greater number of sets of probes than 256 that is the number of chips that can be measured in parallel by the testing apparatus. Further, the probe card 11 is divided into several regions including pairs of regions which are switchable, in addition to a region which is constantly involved in measurement, that is, a region Q constantly supplied with a tester signal. Each pair of the switchable regions are located outside of the region Q and are not adjacent to each other. The pairs of switchable regions include a pair of regions J1 and J2, a pair of regions K1 and K2, a pair of regions L1 and L2, and a pair of regions M1 and M2. These regions are switchable by the relays similarly to the first embodiment, so that, for example, only one of the regions J1 and J2 is supplied with the tester signal. Regions to be supplied with the tester signal are determined for each index.

A description will be made of a case in which a 600-chip wafer is measured by three indexes with the use of the probe card shown in FIG. 7, with reference to FIG. 8.

The regions of the wafer measured by the respective indexes are indicated by the bold lines, while the pair of regions supplied with the tester signal in the respective indexes are indicated by the thin lines. In the first index, the regions J2, K2, L1, and M2 are selected in addition to the region Q. In the second index, the regions J2, K1, L2, and M1 are selected in addition to the region Q. In the third index, the regions J1, K1, L1, and M1 are selected in addition to the region Q. FIG. 8 shows only the regions which are supplied with the tester signal instead of the profile of the probe card. As seen from FIG. 8, the regions are selected to correspond to the periphery of the semiconductor wafer 10, whereby the size of the useless regions in the periphery is reduced. Therefore, although four measurements are required according to the conventional techniques, the present invention is capable of completing the measurement of the wafer by three measurements, leading to improvement of the measurement efficiency.

The probe card according to the second embodiment is also provided with sets of probes corresponding to a greater number of chips than the number of chips that the tester can measure in parallel. A region having a plurality of sets of probes corresponding to the chips is divided into a plurality of regions. The tester signal to a pair of divided regions is switched to supply the tester signal to one of the pair of regions. The switching of the tester signal makes it possible to change the object to be measured by the probe card in accordance with the arrangement of the chips on the semiconductor wafer, and thus to eliminate the useless portions in the periphery of the wafer. Accordingly, the measurement can be performed more efficiently. The efficient measurement makes it possible to reduce the number of testers required.

Although the present invention has been described based on the preferred embodiments thereof, it is not limited to these embodiments. The present invention can be otherwise variously embodied within the scope of the invention, and it will be understood that these changes and modifications are also covered by the present invention.

What is claimed is:

1. A probe card for use in measurement of a semiconductor wafer having a multiplicity of chips arranged thereon, the probe card comprising a first region in which a multiplicity of probes for testing the chips are arranged therein, the first region including a plurality of pairs of subregions, one of the subregions of at least one of the subregion pairs being selected to be supplied with a tester signal.

2. The probe card according to claim 1, wherein the subregions of each subregion pair are provided with a substantially same number of sets of probes.

3. The probe card according to claim 2, wherein the first region includes, at a substantially central part thereof, a second region supplied with a tester signal at every index, and the subregions of each subregion pair are located outside the second region and not adjacent to each other.

4. The probe card according to claim 3, wherein the plurality of pairs of subregions are four pairs, and one of the subregions in each subregion pair is selected.

5. The probe card according to claim 3, wherein one of the subregions in each subregion pair includes a shape conformed to the outline of the chips arranged on the periphery of the wafer.

6. The probe card according to claim 1, wherein the first region has a polygonal shape, and has convex regions on the periphery thereof.

7. The probe card according to claim 1, wherein the upper and lower halves of the first region are symmetrical in shape to each other.

8. The probe card according to claim 7, wherein the left and right halves of the first region are symmetrical in shape to each other.

9. The probe card according to claim 1, comprising a switching circuit for switching the tester signal to one of the subregions of each subregion pair.

10. A method of measuring a semiconductor wafer having a multiplicity of chips arranged thereon, wherein a probe card comprising a first region in which a multiplicity of probes for testing the chips are arranged and which includes a plurality of pairs of subregions is arranged at a predetermined position according to chip arrangement on the semiconductor wafer, and one of the subregions of at least one of the subregion pairs is selected to be supplied with a tester signal.

11. The method of measuring a semiconductor wafer according to claim 10, wherein the subregions of each subregion pair are provided with a substantially same number of sets of probes.

12. The method of measuring a semiconductor wafer according to claim 11, wherein the first region includes, at a substantially central part thereof, a second region supplied with a tester signal at every index, and the subregions of each subregion pair are located outside the second region and not adjacent to each other.

13. The method of measuring a semiconductor wafer according to claim 12, wherein the plurality of pairs of subregions is four pairs, and one of the subregions in each subregion pair is selected.

14. The method of measuring a semiconductor wafer according to claim 12, wherein one of the subregions in each subregion pair includes a shape conformed to the outline of the chips arranged on the periphery of the wafer.

15. The method of measuring a semiconductor wafer according to claim 10, wherein the first region has a polygonal shape, and has convex regions on the periphery thereof.

16. The method of measuring a semiconductor wafer according to claim 10, wherein the upper and lower halves of the first region are symmetrical in shape to each other.

17. The method of measuring a semiconductor wafer according to claim 16, wherein the right and left halves of the first region are symmetrical in shape to each other.

18. The method of measuring a semiconductor wafer according to claim 10, wherein the tester signal is switched to one of the subregions in each subregion pair by using a switching circuit.
